(19) United States
(12) Patent Application Publication
(10) Pub. No.: US 2002/0048905 A1
(43) Pub. Date: Apr. 25, 2002

(54) Chip-type semiconductor device

(76) Inventors: Gorou Ikegami, Shiga (JP); Takao Miyoshi, Shiga (JP)

Correspondence Address: ROSENMAN & COLIN LLP, 575 MADISON AVENUE, NEW YORK, NY, 10022-2585, US

(21) Appl. No.: 09/939,457

(22) Filed: Aug. 24, 2001

(30) Foreign Application Priority Data
Aug. 25, 2000 (JP) 2000-255126

(51) Int. Cl. H01L 21/46; H01L 21/78; H01L 21/301

(52) U.S. Cl. 438/464

(57) ABSTRACT

A semiconductor chip has a plurality of front protruding electrodes and a plurality of rear film electrodes. The front electrodes are connected to interconnect lines made of a metallic film. The semiconductor chip is mounted on a printed circuit board by mounting the rear film electrodes on respective terminals of the printed circuit board and the metallic film is connected to other terminals of the printed circuit board by bonding wires. A large number of semiconductor chips can be fabricated in a simple process at a time.

### BACKGROUND OF THE INVENTION

(a.) Field of the Invention

The present invention relates to a chip-type semiconductor device and a method for fabricating the same.

(b.) Description of the Related Art

In portable electronic apparatuses such as a video camera and a notebook personal computer, there are increasing demands for smaller dimensions and smaller weight thereof. Therefore, semiconductor devices used in the portable electronic apparatuses are also requested to have as smaller dimensions as possible. For obtaining such smaller dimensions, some semiconductor devices have a lead frame structure, and for further smaller dimensions, other semiconductor devices have another structure such as described in JP-A-58-218142.

To obtain the structure described in the above publication, a resin lattice frame having an array of openings is adhered onto a metallic plate to thereby form a bottom plate for each of cell partitions, followed by placing a semiconductor chip on the bottom plate in each of the cell partitions. Each of the top openings of the cell partitions is then covered by a flat cap to encapsulate the semiconductor chip in each of the cell partitions. The cell partitions are then separated by cutting the frame of the lattice frame together with the metallic plate to obtain separate semiconductor chip assemblies having smaller dimensions. This process is convenient for fabricating a large number of semiconductor devices at a time; however, has a disadvantage of difficulty in cutting the resin lattice frame and the metallic stem plate at a single step.

Patent Publication JP3033576 discloses another process for fabricating a large number of semiconductor devices at a time. The chip-type semiconductor device obtained by the process is shown in FIG. 1, wherein a semiconductor chip 11 includes a MOSFET (not shown) having source and gate electrodes 12a and 12b on the rear surface of the chip, an insulator resin film 13 covering the rear and the side surfaces of the semiconductor chip 11 except for the tops of the electrodes 12a and 12b, and a drain electrode 14 made of conductive resin and extending from the front surface of the chip 11 to the rear surface, and an overall resin coat 23 covering the semiconductor device on the front and side surfaces thereof. The semiconductor device is mounted on a printed circuit board with the rear surface of the semiconductor device being opposed to the printed circuit board.

The chip-type semiconductor device is obtained by the following steps: adhering a semiconductor wafer including a plurality of chips onto an adhesive sheet; dicing the wafer in one direction to form a plurality of stripe chip groups each including a plurality of chips arranged in one direction; expanding the adhesive sheet to enlarge the gap between the chip groups; applying insulator resin onto the entire top surface of the wafer for exposure of the source and gate electrodes; turning the chip groups up side down and adhering the chip groups onto a tape before removal of the adhesive sheet; dicing the insulator resin between the chip groups; applying conductive resin onto the entire top surface and patterning thereof; and dicing the conductive resin and the insulator resin between the chip groups; dicing the chip groups to form a plurality of separate chips; and forming the overall coat on the front and side surfaces of the semiconductor chip.

The chip-type semiconductor device as obtained above has an advantage of smaller dimensions and can be mounted on the printed circuit board using a surface mounting technique. However, reduction of the number of process steps therefor and thus the reduction of the fabrication cost is not sufficient in the chip-type semiconductor device disclosed in the patent publication.

### SUMMARY OF THE INVENTION

In view of the above problems in the conventional techniques, it is an object of the present invention to provide a chip-type semiconductor device having smaller dimensions and capable of being fabricated at a lower cost due to a large number of semiconductor devices being fabricated by a single process at a time.

The present invention provides a semiconductor device including a semiconductor chip having a plurality of film electrodes on a rear surface of the semiconductor chip and a plurality of protruding electrodes on a front surface of the semiconductor chip, an insulator resin film covering the semiconductor chip while exposing the film electrodes and a top portion of each of the protruding electrodes, and a conductive film formed on the protruding electrodes and forming a plurality of interconnect lines.

The present invention also provides a method for fabricating a semiconductor device including the steps of: adhering onto an adhesive sheet a semiconductor wafer having a plurality of film electrodes on a rear surface of the semiconductor wafer and a plurality of protruding electrodes on a front surface of the semiconductor wafer, with the rear surface being in contact with the adhesive sheet; dicing the semiconductor wafer to form a plurality of semiconductor chips each including a plurality of the film electrodes and a plurality of the protruding electrodes; extending the adhesive sheet to increase a gap between each two of the semiconductor chips; applying liquid insulator resin to cover the semiconductor chips on the adhesive sheet and fill the gaps therebetween; curing the liquid insulator resin; removing a portion of the insulator resin to expose top surfaces of the protruding electrodes from the resin; forming a conductive film on the top surfaces of the protruding electrodes and on the insulator resin; and dicing the insulator resin and the adhesive sheet to separate the semiconductor chips.

In accordance with the semiconductor device of the present invention and the semiconductor device fabricated by the method of the present invention, a large number of semiconductor devices can be fabricated by a simple process at a time, thereby reducing the fabrication cost for the semiconductor device.

The above and other objects, features and advantages of the present invention will be more apparent from the following description, referring to the accompanying drawings.

### BRIEF DESCRIPTION OF THE DRAWINGS

FIG. 1 is a sectional view of a conventional chip-type semiconductor device:

FIG. 2 sectional view of a chip-type semiconductor device according to an embodiment of the present invention.

FIGS. 3 to 7 are sectional and side views of the semiconductor device of FIG. 2, respectively showing the fabrication steps of a fabrication process.

FIG. 8 is a sectional view of a modification of the semiconductor device of FIG. 2.

FIG. 9 is a sectional view of another modification of the semiconductor device of FIG. 2,

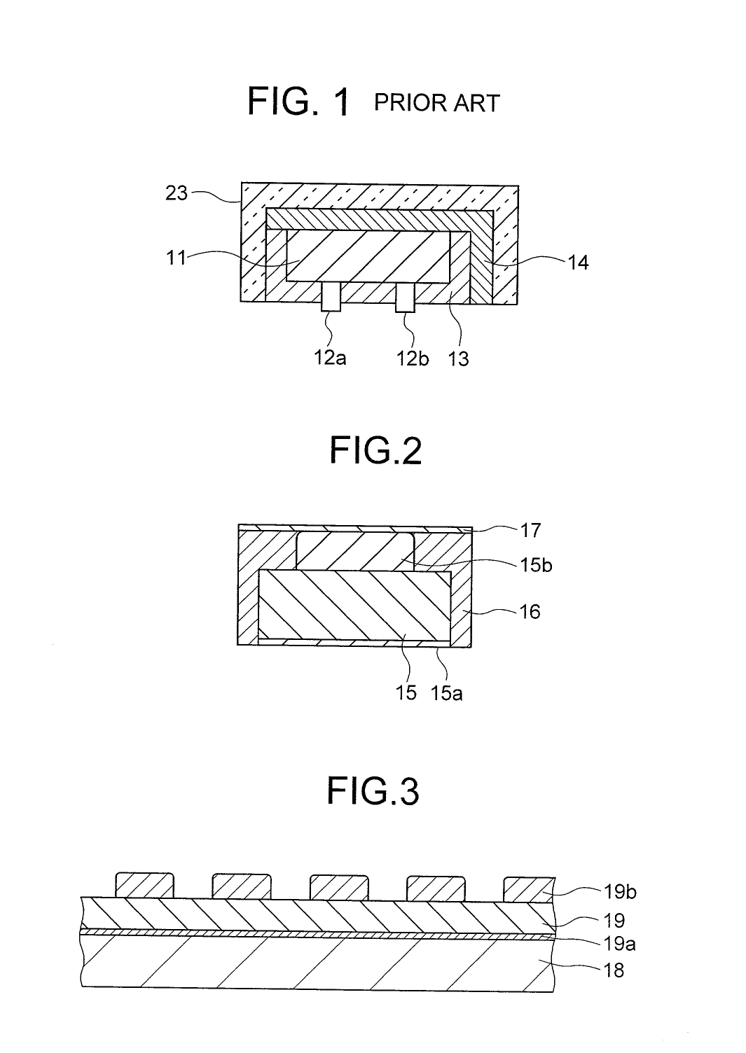

### PREFERRED EMBODIMENTS OF THE INVENTION

Now, the present invention is more specifically described with reference to accompanying drawings, wherein similar constituent elements are designated by similar reference numerals.

Referring to FIG. 2, a chip-type semiconductor device according to an embodiment of the present invention includes: a semiconductor chip 15 having a plurality of film electrodes 15a on the rear surface of the semiconductor chip 15 and a plurality of bump front electrodes 15b protruding from the front surface of the semiconductor chip 15; an insulator resin film 16 formed on entire surfaces of the semiconductor chip 15 while exposing the film electrodes 15a and the top surfaces of the bump front electrodes 15b; and a conductive resin film 17 formed on the front side of the semiconductor chip 15, or on the top surfaces of the bump front electrodes 15b. The conductive resin film 17 is configured as a plurality of interconnect lines connected to the bump front electrodes 15b.

The semiconductor device shown in FIG. 2 is mounted on a printed circuit board, with the rear electrodes 15a being mounted on respective terminals of the printed circuit board for electrical connection. The conductive film 17 constituting interconnect lines is also connected to the terminals of the printed circuit board by bonding wires. In an alternative, the semiconductor device can be sandwiched between a pair of printed circuit boards, with the rear electrodes 15a being mounted on terminals of one of the printed circuit boards and the conductive film 17 being connected to terminals of the other of the printed circuit boards.

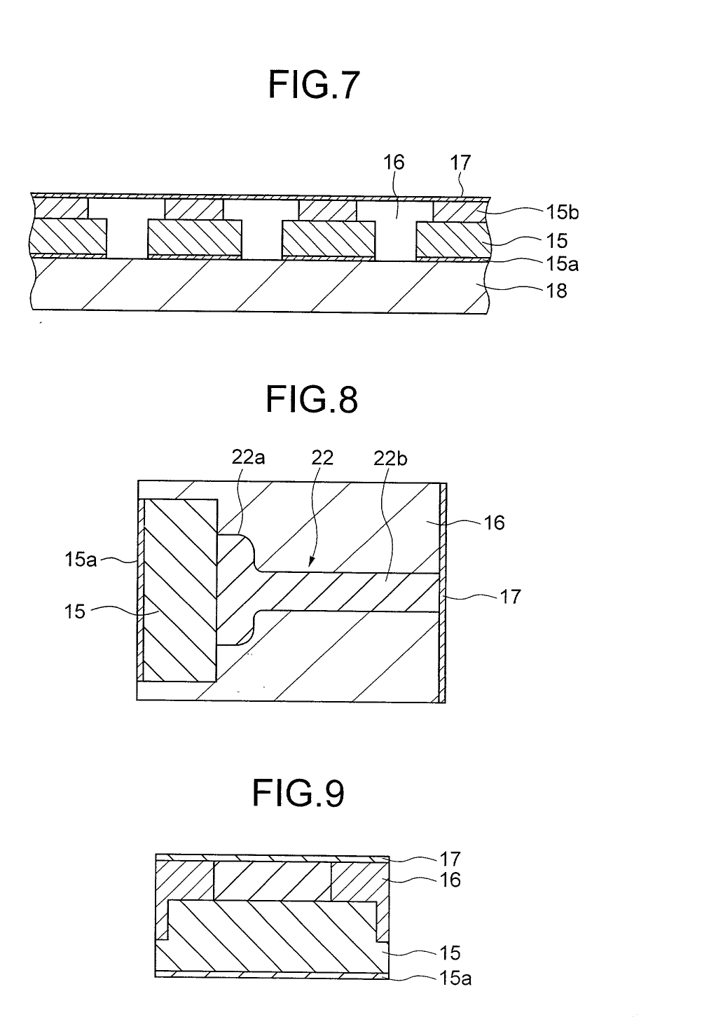

The semiconductor device of FIG. 2 is fabricated by the process as detailed below with reference to FIGS. 3 to 7.

A semiconductor wafer 19 having a plurality of bump electrodes (protruding electrodes) 19b on the front surface thereof and a plurality of film electrodes 19a on the rear surface thereof is adhered onto an adhesive insulator sheet 18 having an elastic or extending property, as shown in FIG. 3. The film electrodes 19a are opposed to the adhesive surface of the adhesive sheet 18.

The resultant wafer on the adhesive sheet 18 is placed on a work table 20, which moves stepwise in Y-direction, turns by 90 degrees after the end of advance, and then moves stepwise in the reverse direction. A rotational blade 21 is disposed above the work table 20 for rotation around the rotational axis 21a, and moves reciprocally in X-direction parallel to the surface of the work table 20. The rotational blade 21 is supplied with a cooling water for cooling the blade 21 and cleaning water for removing the particles generated by dicing the semiconductor wafer 19 using the rotational blade 21.

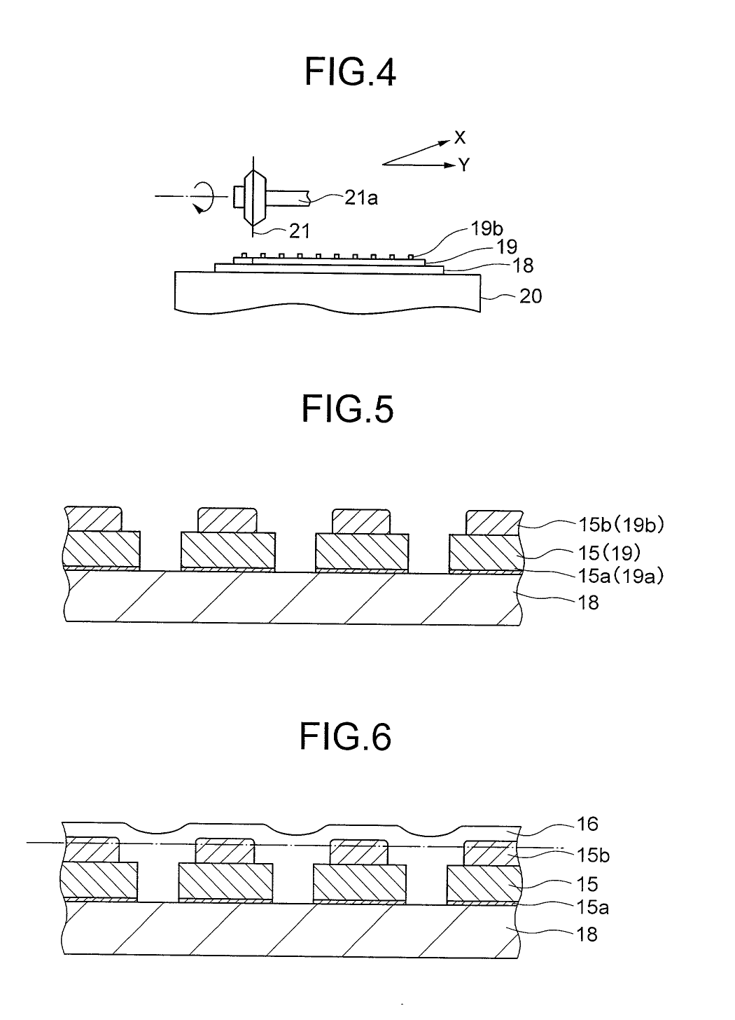

The semiconductor wafer 19 is subjected to dicing using the movement of the work table 20 and the rotational blade 21 in association, while the adhesive sheet 18 is fixed onto the work table 20, thereby forming an array of separate semiconductor chips 15 arranged on the adhesive sheet 18, as shown in FIG. 4.

The resultant array of chips on the adhesive sheet 18 is then taken out from the work table 20, and the adhesive sheet 18 is subjected to extension in the diagonal direction of the arrangement of the semiconductor chips. This allows the gap between each two of the semiconductor chips to increase, as shown in FIG. 5. In FIG. 5, the bump electrodes 19b and the film electrodes 19b shown in FIG. 4 are denoted by symbols 15b and 15a, respectively.

Subsequently, as shown in FIG. 6, a liquid or paste resin 16 is applied onto the entire surface of the diced semiconductor wafer to thereby fill the gap between each two of the semiconductor chips and cover the entire top surface of the semiconductor chips 15 including the bump electrodes 15b. The resultant top surface of the liquid resin film 16 has minor depression above the gap between each two of the semiconductor chips 15, assuming somewhat a lattice structure, which causes a smaller thickness of the portion of the resin film 16 on the bump electrodes 15b. The resin film 16 is cured in this state.

The resultant structure is then subjected to grinding using a grinding machine, which grinds the resin film 16 until the top surfaces of the bump electrodes 15b are exposed. The resultant structure is then transferred to an evaporation reactor to form a metallic film 17 on the entire surface of the resin film 16 and the top surfaces of the bump electrodes 15b. The metallic film 17 is then patterned to form a plurality of interconnect lines. Alternatively, the evaporation of the metallic film 17 may be conducted by using a mask pattern to configure the metallic film into interconnect lines. The metallic film 17 is electrically connected to the bump electrodes 15b, thereby forming external electrodes for the semiconductor chips 15 together with the rear electrodes 15a. The material for the metallic film (or conductive film) is preferably selected from the group consisting of gold, copper and aluminum depending on the material for the bonding. If soldering is used for the bonding, gold or copper may be preferably used for the material for the conductive film 17.

The resultant structure is then diced in X- and Y-directions to cut the resin insulator film 16 and the adhesive sheet 18, followed by removal of the adhesive sheet 18, whereby separate semiconductor devices each having the structure shown in FIG. 2 are obtained.

The process for obtaining the chip-type semiconductor devices of the present embodiment includes only a single step for elastic extension of the adhesive sheet 18 as well as only a single step for application of the liquid insulator resin 16. This reduces the number of process steps for fabrication. In addition, since the dicing step is applied only to the insulator resin film 16 and the adhesive sheet 18, and further the dicing is conducted after the formation of the insulator resin film, the dicing step has no difficulty therein.

The adhesive sheet 18 may be a pressure sensitive resin sheet, or a transparent sheet on which a UV(ultra-violet)-ray sensitive adhesive resin film is formed. In the latter case, after irradiating the adhesive sheet with UV-ray to cure the adhesive sheet, the semiconductor devices can be separated from the adhesive sheet with ease.

A thermo-setting resin or UV-setting resin can be used for the insulator resin film 16 for covering the semiconductor chips 15. This makes a heating process unnecessary and allows the adhesive sheet to be removed with more ease from the semiconductor chips. In the above embodiment, the resin film is subjected to grinding in the grinding machine. However, the resin film 16 may be removed by etching for exposure of the bump electrodes 15b through the resin film 16.

The term “bump electrodes” as recited herein means a pillar electrode or protruding electrode having a relatively flat surface on top thereof, and thus it need not have a circular shape and may be polygon such as square or rectangular shape in cross section thereof. The bump electrode may be replaced by another type of protruding electrode 22, as shown in FIG. 8, which has a base portion 22a having a larger diameter compared to the other portion 22b having a bump shape.

The another protruding electrode 22 shown in FIG. 8 may be obtained by the steps of forming a metallic ball 22a by melting the tip of a metallic wire provided from a capillary tube, pressing the metallic ball 22a with the bottom point of the capillary tube for ease of electrical connection, and cutting the metallic wire by pulling the metallic wire to leave the metallic ball 22a together with a portion of the metallic wire 22b on the semiconductor chip. By selecting the length of the portion of the metallic wire 22b thus left, a desired distance can be obtained between the top of the film electrode 15a and the top of the protruding electrode 15b. This allows a pair of printed circuit boards to be used for sandwiching therebetween the semiconductor chip 15.

The insulator resin film 16 may be removed for exposure of the top surfaces of the bump electrodes by laser to irradiation instead of the grinding. In this case, the bump electrodes 16 and the conductive film 17 can be electrically connected together by using a low-melting-point metal or alloy, e.g., low-melting-point solder.

The conductive film 17 may be formed by evaporation, sputtering and thermal spraying of metal. In the above embodiment, the semiconductor wafer is diced (cut) to form separate chips; however, the semiconductor wafer may be half-cut diced instead, and covered by the insulator resin film 16. The structure obtained by the half-cut dicing is shown in FIG. 9. This process obviates the elastic extension process for the adhesive sheet.

In the structure shown in FIG. 9, side surfaces of the semiconductor chip 15 are exposed from the insulator resin film 16. This structure is suited for electrical connection of the electrodes 15a and 15b on the chip to the terminals on the printed circuit board, if the semiconductor chip is desired to be laid on the side thereof.

In the present invention, a large number of small-size and chip-type semiconductor devices can be fabricated by a simple process at a time.

Since the above embodiments are described only for examples, the present invention is not limited to the above embodiments and various modifications or alterations can be easily made therefrom by those skilled in the art without departing from the scope of the present invention.

What is claimed is:

1. A semiconductor device comprising a semiconductor chip having a plurality of film electrodes on a rear surface of said semiconductor chip and a plurality of protruding electrodes on a front surface of said semiconductor chip, an insulator resin film covering said semiconductor chip while exposing said film electrodes and a top portion of each of said protruding electrodes, and a conductive film formed on said top portion of said protruding electrodes and configured as a plurality of interconnect lines.

2. The semiconductor device as defined in claim 1, wherein said semiconductor chip is mounted on a printed circuit board, with said rear surface opposing said printed circuit board.

3. The semiconductor device as defined in claim 1, wherein said interconnect lines are connected to respective terminals of the printed circuit board by wire bonding.

4. The semiconductor device as defined in claim 1, wherein each of said protruding electrodes has a base portion having a diameter larger than other portion thereof, and said semiconductor chip is sandwiched between a pair of printed circuit boards.

5. The semiconductor device as defined in claim 1, wherein a portion of a side surface of said semiconductor chip is exposed from said insulator resin film.

6. A method for fabricating a semiconductor device comprising the steps of: adhering onto an adhesive sheet a semiconductor wafer having a plurality of film electrodes on a rear surface of said semiconductor wafer and a plurality of protruding electrodes on a front surface of said semiconductor wafer, with said rear surface being in contact with said adhesive sheet; dicing said semiconductor wafer to form a plurality of semiconductor chips each including a plurality of said film electrodes and a plurality of said protruding electrodes; extending said adhesive sheet to increase a gap between each two of said semiconductor chips; applying liquid insulator resin to cover said semiconductor chips on said adhesive sheet and fill the gaps therebetween; curing said liquid insulator resin; removing a portion of said insulator resin to expose top surfaces of said protruding electrodes from said insulator resin; forming a conductive film on said top surfaces of said protruding electrodes and on said insulator resin; and dicing said insulator resin and said adhesive sheet to separate said semiconductor chips.

7. The method as defined in claim 6, wherein said adhesive sheet is a transparent sheet having an extension property and covered with a UV-cured adhesive layer.

8. The method as defined in claim 6, wherein said insulator resin is a UV-cured resin.

9. The method as defined in claim 6, wherein said removing step is a grinding step.

10. The method as defined in claim 6, wherein each of said protruding electrodes has a base portion having a larger diameter than other portion having a bump shape.

11. The method as defined in claim 6, wherein said removing step is a laser irradiation step.

12. The method as defined in claim 6, wherein said protruding electrodes are electrically connected to said conductive film via a low-melting-point metal or alloy.

13. The method as defined in claim 6, wherein said semiconductor wafer dicing step is a half-cut dicing step.
